(19) United States
(12) Patent Application Publication
(10) Pub. No.: US 2002/0080592 A1
(43) Pub. Date: Jun. 27, 2002

(54) Protection for radiated electromagnetic susceptibility during concurrent maintenance

(76) Inventors: Scott Lee Christopherson, Rochester, MN (US); Edward Charles Gillard, Mantorville, MN (US); Don Alan Gilliland, Rochester, MN (US)

Correspondence Address: Scott A. Stinebruner, Wood, Herron & Evans, L.L.P., 2700 Carew Tower, 441 Vine Street, Cincinnati, OH, 45202, US

(21) Appl. No.: 09/747,245

(22) Filed: Dec. 21, 2000

(51) Int. Cl. H05K 9/00

(52) U.S. Cl. 361/818

(57) ABSTRACT

Concurrent maintenance of an electronic system, such as a computer system, is performed in the presence of potentially disruptive Electromagnetic Interference (EMI) by shrouding components within the computer system with a grounded, electromagnetic shielding sheet. In particular, Radiated Electromagnetic Susceptibility (RES) of the computer system is protected when an opening formed in an enclosure of the computer system is shrouded by the electromagnetic sheet. Slits or openings are formed in the sheet to allow access to the components within the shielded system. The sheet is formed of a static shielding polymer with a thin metal layer, and is grounded with an attached grounding member.

### FIELD OF THE INVENTION

The invention is generally related to Electromagnetic Interference (EMI) protection of electronic systems, and more particularly, to protection from Radiated Electromagnetic Susceptibility (RES) during concurrent maintenance of an electronic system.

### BACKGROUND OF THE INVENTION

Concurrent maintenance, when referring to computer systems, is the ability to diagnose problems and correct failures without affecting the system's overall operation. During concurrent maintenance, the computer system continues to perform its intended function while a user gains access to failed components and replaces them. Concurrent maintenance is important as customers' requirement for system availability approach 100%.

The design of computer systems increasingly allows continued operation in the presence of failures. Built-in diagnostic routines identify system failures and reconfigure the computer system to continue operating with redundant components and processes. The identified system failures are communicated to users so that concurrent maintenance may be performed.

Computer systems are increasingly incorporating features for ease of maintenance to correct the diagnosed failures. Enclosures of the computer system include readily removed panels for accessing internal components and subassemblies. Electrical and structural connections allow for easy removal and replacement of these components and subassemblies. The simplified maintenance of electronic systems reduces the training requirements for maintenance personnel as well as decreasing the time required to perform maintenance.

However, requirements for ease of maintenance tend to conflict with requirements for electrical protection. In particular, the electronic components of the computer system are prone to electromagnetic compatibility (EMC) problems from peripheral components of the computer system, to radiated electromagnetic susceptibility (RES) problems due to the environment outside of the computer system, and to electrostatic discharge (ESD) problems from charged surfaces that come into contact with the electronic components during maintenance.

To an extent, the circuit design and the packaging of electronic components mitigates EMC and ESD problems. Internal metal structures of the computer system are provided with AC grounds. Cable terminations and connectors are electrically filtered to protect vulnerable electronics.

The amount of shielding features used increases the complexity, cost, weight and size of the computer system, and may limit performance. Consequently, the extent of shielding features used inside of the enclosure is generally limited to that necessary for EMC with respect to the other internal components. Sources of EMC within the enclosure can be measured for frequency and power intensity. Design options are employed to filter specific frequency ranges induced in other components and to physically separate and shield sensitive components.

Unlike EMC and ESD problems, protection from RES problems is more difficult to address due to the unpredictability of the environment in which the computer system will be used. For instance, the computer system may be placed near a strong radio transmitter or radar station. Thus, electromagnetic interference (EMI) has a power level and frequency range that is largely unpredictable.

Protection from RES problems is also difficult to address due to feasibility. The ideal RES protection would be a steel box, a quarter inch thick, with no holes and all seams solidly welded shut. Of course, this is not practical because provisions must be made to attach power, remote terminals and assorted peripherals, as well as allowing for cooling air flow or other cooling means.

Enclosures of electronic systems approximate the ideal RES protection through a combination of close fitting panels provided with EMI seals where needed. Signal and power wires entering the enclosure are shield grounded to the enclosure and filtered as necessary. Consequently, electronic systems are generally protected from RES problems.

However, this RES protection is compromised during concurrent maintenance. The enclosure is opened for accessing components, allowing electromagnetic interference to induce noise within the electronic system. Often, this noise causes computation errors that forces a system shutdown, necessitating time consuming restart procedures and disrupting processes performed by the electronic system.

Consequently, there is a significant need for an improved method and apparatus for performing concurrent maintenance on electronic systems that avoids problems associated with Radiated Electromagnetic Susceptibility (RES).

### SUMMARY OF THE INVENTION

The invention addresses these and other problems associated with the prior art by providing a grounded electromagnetic shielding sheet and method of using the same to prevent damage or interruption of service to an electronic system during concurrent maintenance on the system.

In accordance with one aspect consistent with the invention, a sheet of electromagnetic shielding material is sized to overlay a portion of the electronic system. A slit formed in the sheet is sized for accessing the components within the electronic system. A grounding member is configured for electrically conductive attachment to the sheet and to a ground.

In accordance with another aspect of the invention, a method provides shrouding at least a portion of an enclosure of the electronic system with a sheet of shielding material while the electronic system is operating. The sheet is grounded. Then, concurrent maintenance is performed on components within the electronic system.

These and other advantages and features, which characterize the invention, are set forth in the claims annexed hereto and forming a further part hereof. However, for a better understanding of the invention, and of the advantages and objectives attained through its use, reference should be made to the Drawings, and to the accompanying descriptive matter, in which there are described exemplary embodiments of the invention.

### BRIEF DESCRIPTION OF THE DRAWINGS

FIG. 1 is a perspective view of an electromagnetic shielding sheet in accordance with one aspect of the present invention shown shrouding an electronic system; and

FIG. 2 is a flow diagram of a procedure for protecting an electronic system from radiated electromagnetic susceptibility (RES) during concurrent maintenance.

The accompanying drawings, which are incorporated in and constitute a part of this specification, illustrate embodiments of the invention and, together with a general description of the invention given above, and the detailed description of the embodiments given below, serve to explain the principles of the invention.

### DETAILED DESCRIPTION

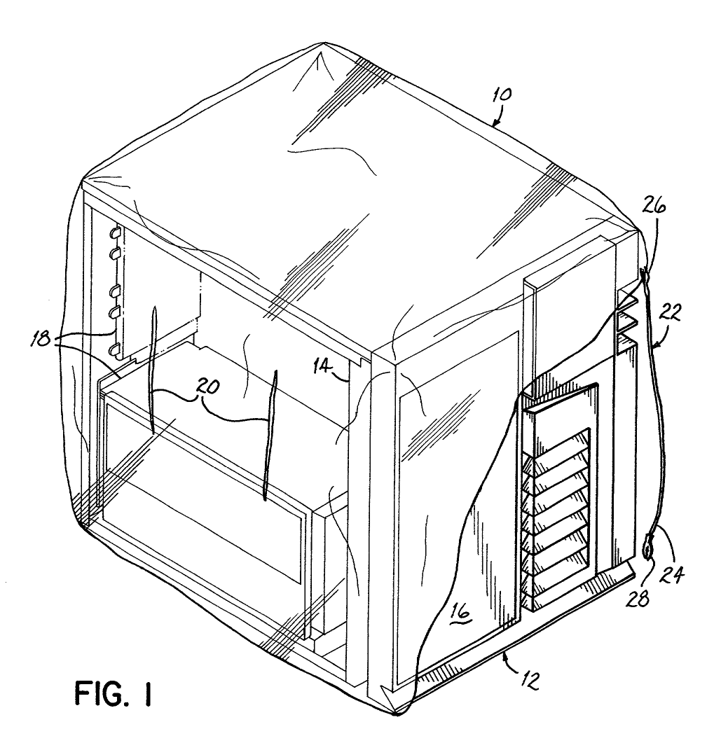

Referring to FIG. 1, a substantially transparent and electromagnetically shielding sheet 10 is shown in accordance with the principles of the present invention draped over an electronic system, depicted as a computer system 12. In particular, the sheet 10 covers an opening 14 in an enclosure 16 of the computer system 12. The opening 14 is formed by the removal of a panel (not shown) for accessing components 18 within the enclosure 16. The electromagnetically shielding sheet 10 protects the components 18 from electromagnetic interference (EMI) from outside the enclosure 16, preventing system shutdowns due to radiated electromagnetic susceptibility (RES).

The electromagnetically shielding sheet 10 is advantageously a metallized polymer comprised of a thin metal coating such as aluminum on a static shielding polymer film substrate (e.g., anti-static polyester, anti-static polyethylene). The thin metal coating provides a Faraday Cage Effect by preventing or reducing penetration of electromagnetic fields into the computer system 12.

The thin metal coating may be on the inside surface, the outside surface, or buried inside the polymer film substrate. Preferably, the sheet 10 is substantially transparent (e.g., about 40% light transmission) to allowing viewing of shrouded components 18. Improved transparency is often achieved with the thin metal coating on the inside of the polymer film substrate rather than on the outside.

For example, one suitable sheet 10 is cut to size from a roll of static shielding bag material, or several static shielding bags may be opened up and taped together with copper tape to form the appropriate size enclosure. The static shielding material can be obtained from Static Control Components, Inc., Simco, or 3M.

It should be appreciated that other types of material may be used for the sheet 10. For example, rather than a solid thin metal coating, a grid of metal may enhance visibility through a substrate yet provide sufficient RES protection.

Access to the components 18 is assisted by one or more slits 20 formed in the sheet 10 and arranged over the opening 14. The slits 20 advantageously tend to close when a user is not accessing the components 18. The slits 20 are either pre-existing or readily cut into the sheet 10 after draping over the computer system 12.

It is understood that other slits 20 in the sheet 10 may comprise flaps, stretchable apertures, or other types of openings.

The sheet 10 is grounded by a grounding member 22, depicted as an electrical wire 24 terminated with alligator clips 26, 28. The grounding member 22 is attached and electrically coupled to the sheet 10 and to a ground (not shown). The ground may be accessed by attaching the alligator clip 28 to the enclosure 16 or to an external ground.

In some applications, the sheet 10 is shaped to conform to at least a portion of the shape of the computer system 12. Also, gripping devices may be included such as adhesive strips, magnetic strips, or hooks to assist in securing the sheet 10 to the enclosure 16. In addition, in some applications, a periphery around the opening 14 in the enclosure 16 is electrically conductive. The gripping device (not shown) may be advantageously electrically coupled to both the sheet 10 and to the enclosure 16 to ground the sheet 10, and thus act as the grounding member 22.

In some applications, the sheet 10 is placed over a frame (not shown) so that the sheet 10 encompasses the computer system 12, but is spaced away from the enclosure 16. The user may enter the space between the sheet 10 and the enclosure 16 to perform concurrent maintenance.

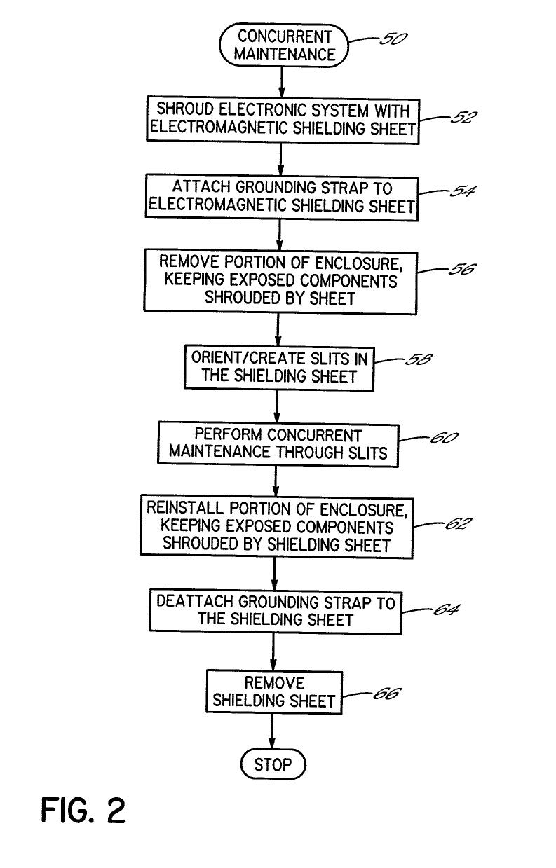

With reference to FIG. 2 a procedure for concurrent maintenance 50 is provided for an electronic system such as a computer system 12. The enclosure 16 is shrouded with a electromagnetic shielding sheet 10 (block 52). A grounding member 22, such as a ground strap, is attached to both the sheet 10 and an appropriate ground (block 54). With the computer system 12 shrouded, a portion of the enclosure 16 is removed to expose components 18 within, such as by removing a panel (block 56). Pre-existing slits 20 in the sheet 10 are oriented, or new slits 20 are made, for removing the panel and accessing the components 18 (block 58).

Depending upon the application, the panel or opening in the enclosure may be made by reaching under or around the sheet 10 rather than working through a slit 20.

Concurrent maintenance is now performed with the computer system 12 continuing to operate, now protected from problems due to Radiated Electromagnetic Susceptibility (RES) (block 60).

Once maintenance is complete, the portion of the enclosure 16 is reinstalled while the components within the computer system 12 are still shrouded by the shielding sheet 10 (block 62). The grounding member 22 is detached from the ground (block 64) and the shielding sheet 10 is removed from the computer system 12 (block 66).

By virtue of the foregoing, there is thus provided an electromagnetic sheet 10 comprised of a thin metal layer and a static shielding polymer layer and a grounding member that is used to shroud components 18 of a computer system 12 during concurrent maintenance. Slits 20 in the sheet 10 allow access as necessary to the components 18. The Faraday Cage Effect provided by the sheet 10 allows uninterrupted operation of the computer system 12 in the presence of Electromagnetic Interference (EMI).

Other modifications may be made to the illustrated embodiments consistent with the invention. Therefore, the invention lies in the claims hereinafter appended.

What is claimed is:

1. A device for protecting components within an electronic system from radiated electromagnetic energy during concurrent maintenance, the device comprising:
a sheet of electromagnetic shielding material sized to overlay a portion of the electronic system;
an opening formed in the sheet and sized for accessing the components within the electronic system; and
a grounding member electrically coupled to the sheet and adapted to be coupled to a ground.

2. The device of claim 1, wherein the sheet comprises a transparent material.

3. The device of claim 1, wherein the sheet comprises a flexible shielding material of a metallized polymer.

4. The device of claim 1, further comprising a gripping device attached to said sheet for removably securing the sheet to the electronic system.

5. The device of claim 4, wherein said gripping device includes an adhesive layer.

6. The device of claim 4, wherein said gripping device is electrically coupled to said sheet and configured to electrically couple to the electronic system.

7. The device of claim 1, wherein the opening is a slit.

8. The device of claim 1, wherein the opening is a closable flap.

9. A method of performing concurrent maintenance on an electronic system, the method comprising:
shrouding at least a portion of an enclosure of the electronic system with a sheet of shielding material while the electronic system is operating;
grounding the sheet; and
performing concurrent maintenance on the electronic system.

10. The method of claim 9, further comprising:
opening the enclosure with the sheet shrouding components within the electronic system.

11. The method of claim 9, further comprising:
forming a slit in the sheet for accessing the shrouded components within the electronic system.

12. The method of claim 9, further comprising:
closing the enclosure with the sheet shrouding components within the electronic system.

13. The method of claim 9, further comprising:
attaching the sheet to the electronic system.
